(19) United States
(12) Patent Application Publication
(10) Pub. No.: US 2023/0028942 A1
(43) Pub. Date: Jan. 26, 2023

(54) Rinsing Composition and Method for Treating Surface of Photoresist Material Using Same

(71) Applicant: 3M INNOVATIVE PROPERTIES COMPANY, St. Paul, MN (US)

(72) Inventors: Changwan BEA, Gyeonggi-do (KR); Taeyong PARK, Gyeonggi-do (KR)

(21) Appl. No.: 17/782,115

(22) PCT Filed: Dec. 2, 2020
(86) PCT No.: PCT/IB2020/061393

§ 371 Date: Jun. 2, 2022

(30) Foreign Application Priority Data
Dec. 3, 2019 (KR) 10-2019-0159055

(51) Int. Cl. C11D 11/00; C11D 1/00; C11D 3/30; C11D 3/43; G03F 7/42

(52) U.S. Cl. CPC C11D 11/0047; C11D 1/004; C11D 3/30; C11D 3/43; G03F 7/426

(57) ABSTRACT

The rinsing composition according to embodiments of the present invention includes a non-ionic fluorinated surfactant and a basic additive containing tetraalkylammonium hydroxide in a specific range of content, so as to reduce the number of defects possibly occurring in a pattern after development of photoresist in a fine patterning process, while preventing pattern collapse.

### TECHNICAL FIELD

The present invention relates to a rinsing composition and a method for surface treatment of photoresist material using the same, more particularly, to a rinsing composition which includes a non-ionic fluorinated surfactant and a basic additive, as well as a method for surface treatment of photoresist material using the same.

### BACKGROUND

Photoresist is a chemical coating that can represent a fine pattern formed in advance on a photomask through photochemical reaction derived from light on a desired substrate. The photoresist is a polymeric material employed in lithography along with the photomask and is considered as a significant factor to directly influence upon the density of an element and to determine the limit of final resolution.

In order to manufacture a high resolution flat panel display, a photo-lithography process is generally used to form fine patterns on a substrate using the photoresist described above. Specifically, photo-lithography is a method of exposing a substrate to the light of a certain wavelength after applying photoresist to the substrate utilizing thermal, mechanical and/or chemical properties of the photoresist, followed by dry or wet-etching.

However, when an aspect ratio on a photoresist pattern is increased to form fine patterns, there is a problem that pattern collapse is likely to occur. The reason why the collapse of photoresist pattern with a high aspect ratio is likely to occur is because, due to high surface tension of deionized (DI) water when the photoresist is washed with DI water after development, the DI water cannot easily escape from the pattern having a high aspect ratio and also cannot uniformly escape therefrom, hence causing a difference in forces acting to the pattern and resulting in occurrence of pattern collapse.

Further, it is difficult to remove defects of the patterned photoresist during progression to fine patterns, in particular, defects occurring in a fine patterning process with high process costs may become critical defects in a final product, causing increase in production costs. Therefore, in order to prevent pattern collapse in the fine patterning process and remove such defects as described above, a variety of studies is now implemented.

Among the studies, one is a process of preventing pattern collapse using a rinsing composition after development of photoresist pattern and then removing defects of the photoresist. Prevention of fine pattern collapse and reduction of defects using a rinsing composition have an advantage of directly using existing photoresist per se, in addition, a process margin can be improved using the rinsing composition thereby expecting an increase in yield.

However, as shown in FIG. 1, diverse defects may happen even using the rinsing composition. Further, even when the photoresist is washed or cleaned using the rinsing composition several times, there is still limitation in reducing the number of residual defects.

### SUMMARY

### Technical Problem to be Solved

Therefore, the present invention has been designed to solve the above-mentioned problems.

It is a first object of the present invention to provide a rinsing composition that can prevent pattern collapse and reduce defects after developing photoresist in a fine patterning process.

It is a second object of the present invention to provide a surface treatment method for forming a photoresist pattern with excellent quality by applying the rinsing composition described above.

### Technical Solution

In order to accomplish the first object, there present invention provides a rinsing composition, including: a non-ionic fluorinated surfactant; and a basic additive containing tetraalkylammonium hydroxide, wherein the tetraalkylammonium hydroxide is included in an amount of 0.01 to 2.38% by weight (“wt. %”) based on a total weight of the rinsing composition.

In order to accomplish the second object, the present invention provides a method for surface treatment of a photoresist material, which includes exposing the photoresist material to the rinsing composition described above.

### Effects of Invention

The rinsing composition of the present invention may reduce the number of defects possibly occurring in the photoresist pattern after developing photoresist in a fine patterning process and prevent pattern collapse.

### BRIEF DESCRIPTION OF THE DRAWINGS

FIG. 1 illustrates defects occurring in a pattern after typical formation of photoresist fine patterns.

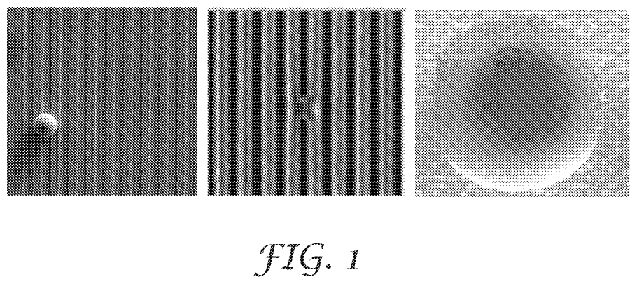

### DETAILED DESCRIPTION

The preset invention is not particularly restricted to the following description but may include various modifications so far as the gist of invention is not altered.

The terms “include” or “comprise” described herein should be construed to further include other components unless specified otherwise. Further, all numerals and expressions indicating amounts of components, reaction conditions, etc. described in the present specification should be understood to be defined with the term of “about” in all cases unless specified otherwise.

The rinsing composition of the present invention may include: a non-ionic fluorinated surfactant; and a basic additive containing tetraalkylammonium hydroxide, wherein the tetraalkylammonium hydroxide is included in an amount of 0.01 to 2.38 wt. % based on a total weight of the rinsing composition.

According to an embodiment of the present invention, since the rinsing composition includes a non-ionic fluorinated surfactant and a basic composition containing a specific content of tetraalkylammonium hydroxide, the number of defects possibly occurring in a pattern after photoresist development in a fine patterning process may be reduced, while preventing pattern collapse.

In general, a developable bottom anti-reflective coating (DBARC) layer is used in order to prevent the pattern from being influenced by light reflection on a bottom membrane and increase adhesion between an organic material and the bottom membrane (inorganic material), which in turn improves pattern standing wave phenomenon. If the rinsing composition according to the embodiment of the present invention is used, the number of defects possibly occurring in a pattern may be significantly reduced even without the D-BARC layer.

Meanwhile, it is needed to reduce surface tension of the rinsing composition in order to prevent pattern collapse. However, it could not be ensured that pattern collapse is definitely prevented even with a low surface tension value. The surface tension value may be decreased by simply increasing a content of the surfactant in the rinsing composition. However, if the content of the surfactant is too high, side effects of melting the photoresist pattern may be caused. Therefore, it is important to control types of the surfactant included in the rinsing composition and am amount thereof to be used.

According to one embodiment of the present invention, the surfactant included in the rinsing composition may include a non-ionic fluorinated surfactant, specifically, a compound represented by Formula 1 below:

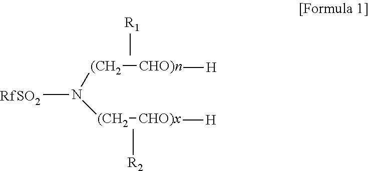

wherein Rf is a perfluoroalkyl group having 3 to 8 carbon atoms;

R₁ and R₂ are each independently H or CH₃;

n ranges 1 to 6; and

x ranges 1 to 6.

More particularly, with regard to the non-ionic fluorinated surfactant, Rf in Formula 1 may be a perfluoroalkyl group having 2 to 6 carbon atoms, a perfluoroalkyl group having 3 to 5 carbon atoms, a perfluoroalkyl group having 3 or 4 carbon atoms, or a perfluoroalkyl group having 4 or 5 carbon atoms.

For example, with regard to the non-ionic fluorinated surfactant, Rf in Formula 1 is a perfluoroalkyl group having 2 to 6 carbon atoms; R₁ and R₂ are each independently H; n ranges from 1 to 5; and x ranges from 1 to 5.

Further, Rf in Formula 1 is a perfluoroalkyl group having 3 to 5 carbon atoms; R₁ and R₂ are each independently H; n ranges from 1 to 3; and x ranges from 1 to 3.

Further, Rf in Formula 1 is a perfluoroalkyl group having 3 to 4 carbon atoms; R₁ and R₂ are each independently H; n ranges from 1 to 2; and x ranges from 1 to 2.

Further, Rf in Formula 1 is a perfluoroalkyl group having 4 to 5 carbon atoms; R₁ and R₂ are each independently H; n ranges from 1 to 2; and x ranges from 1 to 2.

Further, Rf is a perfluoroalkyl group having 4 carbon atoms; R₁ and R₂ are each independently H; n is 2; and x is 1.

The non-ionic fluorinated surfactant may include a compound represented by Formula 1-1.

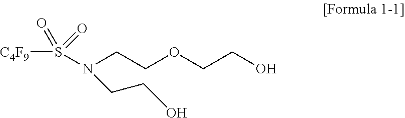

The non-ionic fluorinated surfactant may reduce surface tension of the rinsing composition to maximize wetting properties of the rinsing composition, so that the rinsing composition can easily penetrate into a fine pattern to thus perform ultrafine cleaning required in fine patterning and manufacturing processes. Specifically, the non-ionic fluorinated surfactant may exhibit excellent surface tension reduction effects, may be more effective in application to solvents or water and may have superior wetting properties, as compared to hydrocarbon-based surfactants.

The non-ionic fluorinated surfactant may have surface tension of about 21 dyne/cm or less at a critical micelle concentration (CMC) of 500 ppm, and about pH 6.5.

Further, a solution containing 200 to 500 ppm of the non-ionic fluorinated surfactant may have surface tension of about 20 to 30 dyne/cm. More particularly, the solution containing 200 ppm of the non-ionic fluorinated surfactant may have surface tension of 30 dyne/cm or more, the solution containing 350 ppm of the same may have surface tension of 25 dyne/cm to less than 30 dyne/cm, the solution containing 500 ppm of the same may have surface tension of 20 dyne/cm to less than 25 dyne/cm, and the solution containing 800 ppm of the same may have surface tension of less than 20 dyne/cm.

The non-ionic fluorinated surfactant may be included in an amount of several tens ppm to 1 wt. % based on a total weight of the rinsing solution. Further, the non-ionic fluorinated surfactant may be included in an amount of 10 to 5000 ppm, 20 to 2000 ppm, 50 to 1000 ppm, 100 to 1000 ppm, 200 to 1000 ppm, 100 to 700 ppm, 701 to 2000 ppm, 450 to 1100 ppm, 450 to 1000 ppm, 500 to 1000 ppm, or 300 to 800 ppm based on a total weight of the rinsing composition. If the rinsing composition includes the non-ionic fluorinated surfactant with an amount in the above range, surface tension may be reduced to improve wetting properties. If an amount of the non-ionic fluorinated surfactant is insufficient, reducing the surface tension may be difficult. If the amount is excessive, side effects of melting photoresist pattern may occur.

Further, the rinsing composition according to one embodiment of the present invention may include a basic additive in order to improve defect removal ability on photoresist pattern. The basic additive may include tetraalkylammonium hydroxide in an amount of 0.01 to 2.38 wt. % based on a total weight of the rinsing composition.

Specifically, the above tetraalkylammonium hydroxide may be included in an amount of 0.05 to 2.38 wt. %, 0.01 to 2.38 wt. %, 0.08 to 1.5 wt. % or 1.00 to 2.38 wt. % based on a total weight of the rinsing composition. If an amount of tetraalkylammonium hydroxide is less than 0.01 wt. %, effects of removing defects in fine pattern may be insignificant. If the amount exceeds 2.38 wt. %, the photoresist pattern may be molten and thus cause a problem of fine pattern collapse.

With regard to the rinsing composition, when the basic additive includes tetraalkylammonium hydroxide in an amount in the above range, a pH environment similar to a developer, for example, a developer containing 2.38 wt. % tetramethylammonium hydroxide (TMAH) is afforded to thus efficiently clean residual defects.

Specifically, the rinsing composition according to one embodiment of the present invention may have pH in the range of 10 to 13.5, particularly, 10.2 to 13.1, and more particularly, 10.5 to 12.9. Since the composition has pH in the above range, the number of defects may be significantly decreased as compared to when pH is beyond the above range. If pH of the rinsing composition is less than 10, effects of reducing the number of defects are insignificant due to insufficient solubility and thus yield in the corresponding process may he deteriorated. If the pH is more than pH 13.5, a problem such as melting of pattern may occur.

The above tetraalkylammonium hydroxide may include, for example, one or more selected from a group consisting of tetramethylammonium hydroxide, tetraethylammonium hydroxide, tetrapropylammonium hydroxide and tetrabutylammonium hydroxide.

According to an embodiment of the present invention, with regard to the rinsing composition, a mixing ratio of the non-ionic fluorinated surfactant and tetraalkylammonium hydroxide may be 1:0.2 to 48, 1:1 to 48, 1:2 to 48, 1:0.2 to 40, 1:2 to 40, 1:2 to 30, 1:2 to 28, 1:0.2 to 20, 1:20 to 48, or 1:20 to 40 in terms of ratio by weight. When the rinsing composition includes the non-ionic fluorinated surfactant and tetraalkylammonium hydroxide in the above ratio, surface tension may be reduced and pH may be adjusted to desired values, so that wetting properties of the rinsing composition according to the present invention may be enhanced while reducing the number of residual defects in a fine pattern.

The basic additive may include different basic additives other than tetraalkylammonium hydroxide described above, and such different basic additives may include, for example, ammonium hydroxide, benzyltrimethylammonium hydroxide, trimethylvinylammonium hydroxide, etc., which are used alone or as a mixture thereof, but are not limited thereto.

According to one embodiment of the present invention, the rinsing composition may include 10 to 5000 ppm of the non-ionic fluorinated surfactant, 0.01 to 5 wt. % of the basic additive and a solvent as the balance, based on a total weight of the rinsing composition.

According to another embodiment of the present invention, the rinsing composition may include 500 to 1000 ppm of the non-ionic fluorinated surfactant, 0.01 to 4 wt. % of the basic additive and a solvent as the balance, based on a total weight of the rinsing composition.

The solvent may include water, an organic liquid or a combination thereof. The organic liquid may include, for example, methanol, ethanol, benzyl alcohol, isopropyl alcohol, isoamyl alcohol, 2-propanol, 1-pentanol, isobutyl alcohol, butyl alcohol, cetyl alcohol, lauryl alcohol, nonyl alcohol, undecyl alcohol, etc., which are used alone or as a mixture thereof, but is not limited thereto. Further, water used herein may include dionized water (DIW).

The rinsing composition according to an embodiment of the present invention may reduce surface tension of the rinsing composition by 10 to 40% using a non-ionic surfactant.

Specifically, surface tension of the rinsing composition may range from 17 to 25 dyne/cm, 18 to 25 dyne/cm, 20 to 25 dyne/cm, 18 to 21 dyne/cm or 21 to 24 dyne/cm. When the rinsing composition has such surface tension as satisfied in the above range, the rinsing composition can easily penetrate into a fine pattern, thereby reducing the number of defects occurring in the fine pattern.

The rinsing composition according to an embodiment of the present invention may be used in a photoresist pattern forming process that generally uses a developer.

Therefore, according to an embodiment, the present invention may provide a method for surface treatment of photoresist material, which includes exposing the photoresist material to the rinsing composition described above.

Specifically, the method for surface treatment of photoresist material may include: (a) applying the photoresist material to a substrate to form a layer; (b) exposing the photoresist layer and then developing the same to form a pattern; and (c) washing the photoresist pattern with the rinsing composition.

The surface treatment method may further include a soft baking process before the exposure in step (b), or a post baking process after the exposure in step (b), and the baking process may be performed at a temperature of 70 to 200° C.

Further, development may be performed using an alkaline developer, and the alkaline developer used therefor may be 0.01 to 5 wt. % of a tetramethyl ammonium hydroxide (TMAH) solution.

Meanwhile, the exposing process may use KrF (248 nm), ArF (193 nm), EUV (130 nm) or E-beam as an exposure light source, without particular limitation thereof.

As described above, according to the present invention, a washing process using the rinsing composition of the present invention may be performed in the last step (c) including development, for example, positive tone development (DTD). Further, after washing with the rinsing composition, an additional washing process using DIW may be further included.

According to an embodiment of the present invention, when surface treatment is conducted using the rinsing composition, the number of defects in a fine pattern may be remarkably reduced while preventing fine pattern collapse, thereby facilitating pattern formation and thus increasing a process margin. In addition, damage to a bottom silicon oxide layer and a metal layer may be minimized.

Hereinafter, the present invention will be described in more detail by way of the following examples. However, these examples are provided only for illustrative purpose, and the scope of the present invention should not be construed as being limited thereto.

### EXAMPLES

### <Preparation of Rinsing Composition>

### Example 1

With respect to a total weight of a rinsing composition, 500 ppm of non-ionic fluorinated surfactant (Formula 1-1 below, 3M™), 2.38 wt. % of tetramethylammonium hydroxide (TMAH) as a basic additive, and 18 MΩ deionized water (DIW) as the balance were admixed to prepare the rinsing composition.

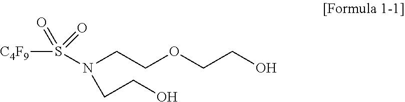

### Example 2

A rinsing composition was prepared by the same method as described in Example 1, except that 2.00 wt. % of TMAH was used.

### Example 3

A rinsing composition was prepared by the same method as described in Example 1, except that 1.00 wt. % of TMAH was used.

### Example 4

A rinsing composition was prepared by the same method as described in Example 1, except that 0.10 wt. % of TMAH was used.

### Example 5

A rinsing composition was prepared by the same method as described in Example 1, except that 0.01 wt. % of TMAH was used.

### Example 6

A rinsing composition was prepared by the same method as described in Example 4, except that 450 ppm of non-ionic fluorinated surfactant was used.

### Example 7

A rinsing composition was prepared by the same method as described in Example 4, except that 700 ppm of non-ionic fluorinated surfactant was used.

### Example 8

A rinsing composition was prepared by the same method as described in Example 4, except that 1000 ppm of non-ionic fluorinated surfactant was used.

### Example 9

A rinsing composition was prepared by the same method as described in Example 4, except that 1100 ppm of non-ionic fluorinated surfactant was used.

### Comparative Example 1

No rinsing composition was used.

### Comparative Example 2

A rinsing composition was prepared by the same method as described in Example 1, except that TMAH was not used.

### EXPERIMENTAL EXAMPLE

### Experimental Example 1: Measurement of Surface Tension

The surface tension described in the examples and comparative examples was measured by Kruss K12 tensiometer. Wilhelmy platinum plate PL12 and a glass sample container were used to execute a program. All materials cited above can be purchased from Kruss USA addressed in Charlotte, N.C. Measured results are shown in Table 1 below.

TABLE 1

| | Rinsing composition | | | Surface tension |
|---|---|---|---|---|
| | Surfactant | TMAH | pH | (dyne/cm) |
| Example 1 | 500 ppm | 2.38 wt. % | 13.1 | 21 |
| Example 2 | | 2.00 wt. % | 12.9 | 21 |
| Example 3 | | 1.00 wt. % | 12.7 | 21 |
| Example 4 | | 0.10 wt. % | 11.4 | 21 |
| Example 5 | | 0.01 wt. % | 10.2 | |
| Example 6 | 450 ppm | 0.10 wt. % | 11.4 | 24 |
| Example 7 | 700 ppm | 0.10 wt % | 11.4 | 20 |
| Example 8 | 1000 ppm | 0.10 wt. % | 11.4 | 18 |
| Example 9 | 1100 ppm | 0.10 wt. % | 11.4 | 17 |
| Comparative | DIW | 0 | 7.0 | |
| Example 1 | | | | |
| Comparative | 500 ppm | 0 | 6.0 to 6.5 | |
| Example 2 | | | | |

| | | | |
|---|---|---|---|
| Reference | 200 ppm | — | 31.7 |
| | 350 ppm | | 26.9 |
| | 500 ppm | | 21 |

### Experimental Example 2: Observation of Defects

A wafer having a pattern (“patterned wafer”) formed using KrF photoresist was washed using each of the rinsing compositions prepared in the examples and comparative examples, followed by assessment of defect removal effects. The used KrF photoresist was applied in a thickness of 14,000 A through spin-coating, so as to form a 1:1 line and space (L/S) pattern with a pattern resolution of 350 nm. An ASML 700D KrF scanner and TEL MARC-8 track were used for fabrication of the patterned wafer.

The 8 inch patterned wafer was exposed to the rinsing composition prepared in each of the examples and comparative examples in order to conduct surface treatment using photoresist. Herein, Comparative Example 1 is a reference example wherein the wafer was treated using a developer containing 2.38 wt. % of tetraalkylammonium hydroxide (TMAH) and then using deionized water without the rinsing composition. On the other hand, the rinsing composition prepared in each of Examples 1 to 5 and Comparative Example 2 was used for surface treatment between treatments using 2.38 wt. % TMAH developer and the deionized water.

After surface treatment using photoresist, in order to detect a critical dimension (CD: line width, unit: μm) of the line pattern and a pattern morphology, Hitachi-9260 CD SEM was used (observation of pattern by AIT XP fusion equipment). The above experiment was repeated three times.

Results of the observation are shown in Tables 2 and 3 below.

TABLE 2

| | Example | | | | | | | | | | | |
|---|---|---|---|---|---|---|---|---|---|---|---|---|
| Remark | 1 | | | 3 | | | 4 | | | 5 | | |
| pH | 13.1 | | | 12.7 | | | 11.4 | | | 10.2 | | |
| Time | 1^{st} | 2^{nd} | 3^{rd} | 1^{st} | 2^{nd} | 3^{rd} | 1^{st} | 2^{nd} | 3^{rd} | 1^{st} | 2^{nd} | 3^{rd} |
| Number of defects | 124 | 108 | 177 | 354 | 216 | 620 | 203 | 131 | 249 | 747 | 625 | 964 |

| | | | | |
|---|---|---|---|---|
| Average number | 136 | 397 | 194 | 779 |
| of defects | | | | |

TABLE 3

| | Comparative Example | | | | | |
|---|---|---|---|---|---|---|
| Remark | 1 | | | 2 | | |
| pH | 7.0 | | | 6.0 to 6.5 | | |
| Time | 1st | 2nd | 3rd | 1st | 2nd | 3rd |
| Number of defects | 524 | 650 | 1058 | 280 | 375 | 198 |

| | | |
|---|---|---|
| Average number | 744 | 284 |
| of defects | | |

As shown in Tables 2 and 3, in case of Comparative Example 1 without use of the rinsing composition, the surface has 744 defects. On the other hand, it could be seen that the examples using TMAH has significantly reduced defects, as compared to Comparative Example 1 as well as Comparative Example 2 without use of TMAH. Specifically, it could be seen that Examples 1 and 4 using the rinsing composition exhibit most excellent defect removal effects.

Further, defect reduction was compared between a case where the rinsing composition is not used between development and a washing process using dionized water such as Comparative Example 1 and another case where the rinsing composition is used such as Example 3. According to the same procedure described in Experimental Example 2, the rinsing composition prepared in Example 3 was sufficiently applied to photoresist fine pattern (washing amount and washing time: 10 to 40 cc and 6 to 20 seconds). Then, after rotation, defect reduction was observed by KLA equipment (KLA Co.). The observed results are shown in Table 4.

TABLE 4

| | Substrate | | | | | | | |
|---|---|---|---|---|---|---|---|---|
| | With/without | WF | Total | | | | | |
| Comparison | (W/O) D-BARC | No. | number | Blob | Stain | Unique | Dust | Unfound |
| Comparative | W | 1st | 219 | 0 | 24 | 0 | 1 | 194 |
| Example 1 | | 2nd | 51 | 0 | 25 | 0 | 1 | 25 |
| | O | 1st | 45 | 0 | 8 | 0 | 0 | 37 |
| | | 2nd | 27 | 1 | 11 | 0 | 3 | 12 |
| Example 3 | W | 1st | 172 | 0 | 26 | 0 | 0 | 146 |
| | | 2nd | 50 | 8 | 18 | 0 | 1 | 23 |
| | O | 1st | 20 | 3 | 0 | 0 | 7 | 10 |
| | | 2nd | 16 | 4 | 1 | 0 | 3 | 8 |

D-BARC: developable bottom anti-reflective coating

As shown in Table 4, it could be seen that Example 3 using the rinsing composition exhibits remarkably excellent effects of decreasing the number of defects, as compared to Comparative Example 1 without use of the rinsing composition.

Specifically, it was confirmed that Example 3 can reduce the number of defects in an oxide wafer (without D-BARC layer) to about 60%, compared to Comparative Example 1.

1. A rinsing composition, comprising:
a non-ionic fluorinated surfactant; and
a basic additive including tetraalkylammonium hydroxide,
wherein the tetraalkylammonium hydroxide is included in an amount of 0.01 to 2.38% by weight (“wt. %”) based on a total weight of the rinsing composition.

2. The rinsing composition according to claim 1, wherein a content of the non-ionic fluorinated surfactant ranges from 10 ppm to 1 wt. % based on a total weight of the rinsing composition.

3. The rinsing composition according to claim 1, wherein the non-ionic fluorinated surfactant includes a compound represented by Formula 1 below: 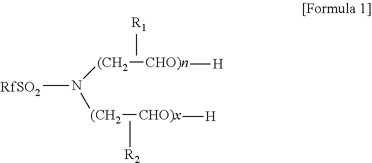
wherein Rf is a perfluoroalkyl group having 3 to 8 carbon atoms;
R₁ and R₂ are each independently H or CH₃;
n ranges 1 to 6; and
x ranges 1 to 6.

4. The rinsing composition according to claim 3, wherein Rf is a perfluoroalkyl group having 2 to 6 carbon atoms; R₁ and R₂ are each independently H; n ranges 1 to 5; and x ranges 1 to 5.

5. The rinsing composition according to claim 1, wherein the tetraalkylammonium hydroxide includes one or more selected from a group consisting of tetramethylammonium hydroxide, tetraethylammonium hydroxide, tetrapropylammonium hydroxide and tetrabutylammonium hydroxide.

6. The rinsing composition according to claim 1, wherein the tetraalkylammonium hydroxide is included in an amount of 0.05 to 2.38 wt. % based on a total weight of the rinsing composition.

7. The rinsing composition according to claim 1, wherein a mixing ratio of the non-ionic fluorinated surfactant and the tetraalkylammonium hydroxide ranges from 1:0.2 to 48 in terms of ratio by weight.

8. The rinsing composition according to claim 7, wherein a mixing ratio of the non-ionic fluorinated surfactant and the tetraalkylammonium hydroxide ranges from 1:1 to 48 in terms of ratio by weight.

9. The rinsing composition according to claim 1, wherein the composition includes 10 to 5000 ppm of the non-ionic fluorinated surfactant, 0.01 to 5 wt. % of the basic additive and a solvent as the balance, based on a total weight of the rinsing composition.

10. The rinsing composition according to claim 9, wherein the solvent includes water, an organic liquid or a combination thereof.

11. The rinsing composition according to claim 10, wherein the solvent includes deionized water (DIW).

12. The rinsing composition according to claim 1, wherein pH of the rinsing composition ranges from 10 to 13.5.

13. The rinsing composition according to claim 1, wherein the composition has surface tension of 17 to 25 dyne/cm.

14. A method for surface treatment of photoresist material, comprising exposing the photoresist material to the rinsing composition according to claim 1.
